(19) United States
(12) Patent Application Publication
(10) Pub. No.: US 2010/0230581 A1
(43) Pub. Date: Sep. 16, 2010

(54) LIGHT SENSOR

(75) Inventors: Johannes Adrianus Petrus Leijtens, Bleiswijk (NL); Jan Hopman, Delft (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: NEDERLANDSE ORGANISATIE VOOR TOEGEPAST- NATUURWETENSCHAPPELIJK ONDERZOEK TNO, Delft (NL)

(21) Appl. No.: 12/293,700

(22) PCT Filed: Mar. 26, 2007
(86) PCT No.: PCT/NL2007/050127

§ 371 Date: Feb. 26, 2009

(30) Foreign Application Priority Data
Mar. 24, 2006 (EP) 06075693.9
Sep. 1, 2006 (EP) 06076663.1

(51) Int. Cl. H01L 27/144

(52) U.S. Cl. 250/208.2

(57) ABSTRACT

Light sensor, comprising a non-translucent layer (1) having a translucent aperture (2), and a sensor array layer (3), comprising an array of op to-electrical sensor elements (3a-d), as well as a translucent solid first carrier layer (4) to which said non-translucent layer is applied at one side and said sensor array layer at the other side. A multitude of such light sensors can be manufactured by taking a first substrate (4) which is suitable as a translucent solid first carrier layer for said multitude of light sensors, applying the non-translucent layers (1) including an aperture (2) in each of them for said multitude of light sensors at one side of the first substrate and applying the sensor array layers (3) for said multitude of light sensors at the other side of the first substrate and, finally, separating the individual light sensors (7a-b). The light sensor may comprise an integrated opto-electric power supply (8, 9).

### FIELD

The invention concerns a light sensor, comprising a non-translucent layer having a first translucent aperture, a first sensor array layer (3) having a number of opto-electrical sensor elements, and spacing means between said non-translucent layer and said sensor array layer, said spacing means comprising a translucent solid first carrier layer located at one side of said first carrier layer and said sensor array layer being located at its other side.

### BACKGROUND

Prior art precision light sensors comprise an aperture comprising membrane which is spaced from an array of opto-electrical sensor elements (sensor array, for brevity's sake) by means of a precise spacing member, keeping the membrane and the opto-electric array at the right position.

The membrane comprises an aperture through which the light shines upon the opto-electrical array, causing a light spot on the sensor array. Using the position of the light spot on the sensor array and the (known) distance between the membrane and the sensor array, the angle of incidence of the light can be measured (or computed).

One prior art sensor is known from the EP publication no. 0613183, disclosing a position measuring element fabricated by forming a photoconductive film on one side of a transparent glass plate and a light shielding film formed on the other side of the glass plate. Although this sensor unit must be powered, the publication is silent on how to do this. In one aspect, it is desirable to provide a cost-efficient and compact way to provide a power supply for a light sensor of the above-identified nature.

In this application, the term light stands for any radiation that is of interest in the electromagnetic spectrum, typically, light in the visible range, as well as UV and/or IR light.

### SUMMARY

Another aspect is to provide a light sensor the manufacturing process of which is more simple. Both aspects result in a light sensor which is less expensive and more reliable. An additional aspect of the invention is to provide a light sensor having an integrated opto-electric power supply.

According to an aspect of the present invention, there is provided a light sensor as defined in claim 1. In particular, there is provided a light sensor, comprising: a non-translucent layer having a first translucent aperture, a first sensor array layer having a number of opto-electrical sensor elements, and spacing means between said non-translucent layer and said sensor array layer, said spacing means comprising a translucent solid first carrier layer located at one side of said first carrier layer and said sensor array layer being located at its other side, wherein said non-translucent layer comprises a second translucent aperture provided at said one side of said translucent first carrier layer and in that a second sensor array layer comprising an array of opto-electrical sensor elements is provided at the other side of said translucent first carrier layer; wherein a processing module is provided on said layer electrically connected to said first and second sensor array layers said second array layer providing an integrated opto-electric power supply to said processing module.

Accordingly, a stand-alone sensor application may be provided that is easily and efficiently manufacturable. Herein, it is considered that, in order that the sensor will provide a meaningful output, the sensor will typically be arranged towards an incident light that can be used to provide power to the sensor, so that the sensor may function on opto-electric power supply only.

Preferably, said non-translucent layer is applied (e.g. deposited) on the surface of the first carrier layer at said one side, e.g. by means of vacuum deposition. In the same way, the sensor array layer may be applied on the surface of the first carrier layer, e.g. by means of vacuum deposition at the other side of e.g. a silicium or CIGS (Copper indium gallium selenide) layer which subsequently can be doped in order to form the desired sensors.

As in practice it may appear to be more complex to apply the sensor array layer on the surface of the first carrier layer, e.g. by means of vacuum deposition and doping, as the characteristics of the translucent first carrier layer, which e.g. may be made of glass or glassy material, may be less suitable for such deposition process.

To meet the possible problem that the material of the translucent (e.g. glassy) first carrier layer may not be very suitable for deposition of the sensor array layer upon it, it may preferred to apply the sensor array layer on a surface of a second carrier layer which is located at said other side (i.e. opposite to the side of the non-translucent layer) of the first carrier layer. The second carrier layer does not need to be translucent, i.e. when the sensor array is applied on the surface of the second carrier which faces towards the first carrier layer. The second carrier layer may e.g. be made of (non-translucent) silicium or CIGS. The sensor array may be made be means op doping the surface of the silicium or CIGS carrier layer (substrate).

By applying the non-translucent (or opaque) layer (a “membrane” with aperture) at one side of (translucent) carrier and assembling the sensor array at the other side, a (mechanically) very robust and compact sensor can be made which can be manufactured cheaply in great number, resulting in broadening the application area of this kind of light sensors.

By applying well-fit materials light sensors can be designed which resist well very high of low temperatures and/or radiation.

By applying a plastic spacer and well-fit materials a sensor can be designed which can be manufactured in a large volume roll-to-roll process, thus leading to very cost effective sensors.

The light sensor preferably comprises a photosensitive structure which is illuminated through the aperture and the translucent carrier. The photosensitive structure may be embodied as silicon photo diodes, quadrature diodes or active pixel sensor elements. In low-cost embodiments quadrature diodes of silicon photo diodes may be preferred.

A digital version of the detector may be provided with an array of “O/E pixels”, formed by een rather large array of e.g. small-sized photo diodes which may scanned and read out in a digital way, thus delivering a digital output signal which can be processed digitally. An analogue version of the detector may comprise a rather small number of e.g. photo diodes (e.g. four as will be shown as an exemplary embodiment), the emitted current (depending of the received light intensity) of which can be processed in an (primarily) analogue form.

The light sensor according to the invention may, additionally, comprise an integrated opto-electric power supply which comprises a second translucent aperture in said non-translucent layer at said one side of said translucent first carrier layer as well as a second sensor array layer comprising an array of opto-electrical sensor elements located—either applied on the opposite surface of the first (translucent)) carrier layer or applied on the surface of a second carrier layer—at the other side of said translucent first carrier layer.

The light sensors may be manufactured by next steps:
take a first substrate which is suitable as a translucent solid first carrier layer for said multitude of light sensors and apply the non-translucent layers including the relevant apertures for said multitude of light sensors on the surface at one side of said first substrate;
apply the sensor array layers for said multitude of light sensors on the surface at the other side of said first substrate, or—to manufacture, optionally, a light sensor having a first carrier layer (e.g. glassy substrate) and a second (e.g. silicium or CIGS substrate) carrier layer—apply, by vacuum deposition plus doping, the sensor array layers for said multitude of light sensors on the surface of a second substrate and assemble the second substrate, including the sensor array layers, to the surface at the other side of the first substrate;
separate the individual light sensors.

In the way outlined here it is possible to make very rigid and stable light sensors with a high degree of reproducibility. Moreover, by illuminating through the (solid, translucent) first substrate there is a very well defined distance between the membrane and the photo sensor array, causing a high degree of precision. Besides, it is possible to manufacture great numbers of sensors having photo-lithographical precision and mutual very small variations.

### EXEMPLARY EMBODIMENT

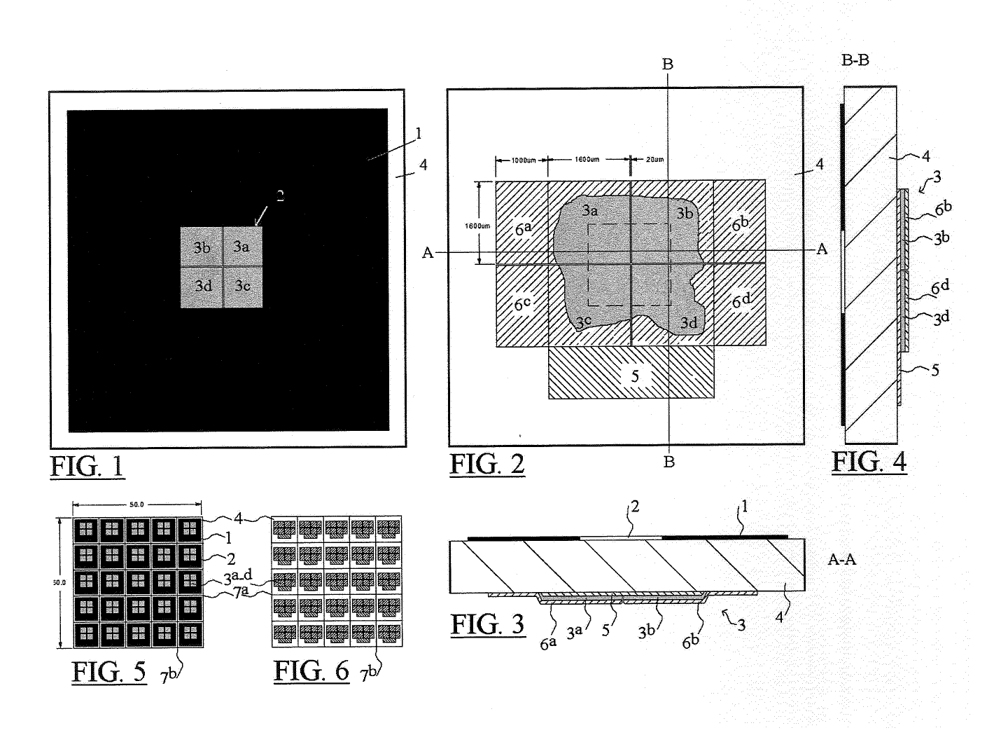

FIGS. 1, 2, 3 and 4 show an exemplary embodiment of an (individual) light sensor.

FIGS. 5 and 6 show an exemplary embodiment of a multitude of light sensors before the separation step has been performed.

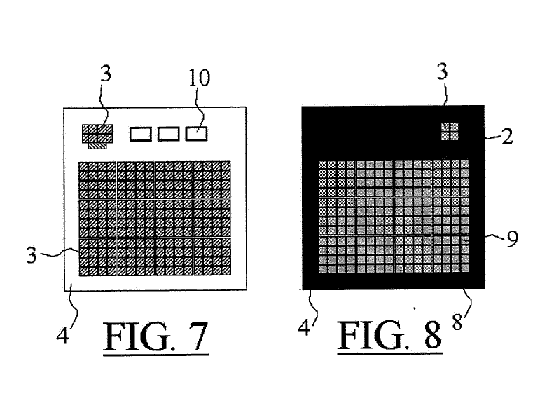

FIGS. 7 and 8 show an exemplary embodiment according to an aspect of the invention, of a light sensor being integrated with a opto-electric power supply and further components.

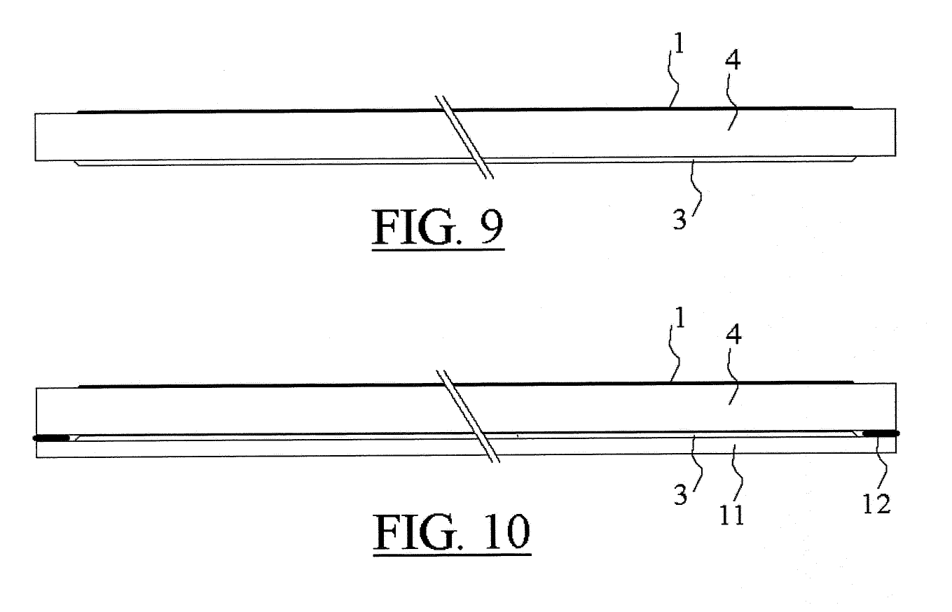

FIG. 9 shows schematically a “single substrate” version of the invention, while

FIG. 10 shows a “ dual substrate” version.

FIG. 1 shows the front side of a light sensor as discussed in the previous paragraph. The light sensor comprises a non-translucent (opaque) layer 1 having a translucent aperture 2 at the front side of a translucent solid first carrier layer 4. The opaque layer 1 may be of Aluminum and applied to the carrier 4 by means of vacuum deposition. The carrier may be made of glass, e.g. Pyrex™ (borosilicate glass). At the carrier's bottom side a sensor array layer 3, comprising an array of opto-electrical sensor elements 3a-d, is applied, e.g. by vacuum deposition and doping. In FIG. 1 the sensor elements 3a-d are visible through the translucent (or transparent) carrier layer 4.

The aperture 2 has about the same size as the four sensor elements. Dependent on the position of the light source the sensor elements 3a-d will generate more or less current. By measuring the ratio between the four currents the position of the light source can be computed.

FIG. 2 shows the sensor's bottom side, showing again the carrier layer 4 and an array of four sensor elements, viz. photo-diodes 3a-d. Moreover, connection electrodes of the photo-diodes are visible, viz. one common electrode and the four individual counter electrodes 6a-d of the four photodiodes 3a-d.

FIGS. 3 and 4 show cross-section A-A and cross-section B-B, showing more in detail the construction of the photo-diodes. The (sub)layers which together form the sensor array layer 3, may all be applied by means of vacuum deposition and doping. The photo-diodes have a common (translucent) electrode 5, e.g. made of Indium Tin Oxide (http://en.wikipedia.org/wiki/Indium_tin_oxide).

The proper opto-electric or photo-voltaic layers 3a-d may be made by Copper Indium di-Selenide (CuInSe₂ or CIS; http://www.azom.com/details.asp?ArticleID=1165). The layers 3a-d are covered by individual electrode layers 6a-d, e.g. of Aluminum.

FIGS. 5 and 6 show a multitude of light sensors—front side and back side respectively—during the phase of their manufacture process before their separation into individual light sensors as shown in FIGS. 1 to 4.

FIGS. 5 and 6 show a first substrate 4 which is suitable as a translucent solid first carrier layer for said multitude of light sensors. FIG. 5 shows the result of applying a vacuum deposition, at one side of the first substrate, of the shape of the non-translucent layers 1 for the multitude of light sensors, including an aperture 2 in each of them. FIG. 6 shows a multitude of photosensitive elements 3a-d at the other side of the first substrate, needed for a multitude of light sensors. Both figures show cutting lines 7a-b along which the individual light sensors are being separated from each other.

FIGS. 7 and 8 show a light sensor with an integrated opto-electric power supply, both, the light sensor and the opto-electric power supply, being build up by similar components. The complete component is build around the translucent (or transparent) carrier layer 4 as present in the previously discussed embodiments. In FIGS. 7 and 8 the upper corner shows a light sensor 2-3 which is similar to the sensors as shown in the previous figures and comprising four photosensitive elements 3(a-d), which can be sunlit via the translucent aperture 2.

A opto-electric power supply element 8 is build up by a plurality of photo sensitive elements which may have a construction which is similar to the individual photo sensitive elements 3 discussed above, viz. comprising (see FIGS. 3 and 4) a common (translucent) electrode, e.g. made of Indium Tin Oxide, opto-electric layers e.g. made of Copper Indium di-Selenide, which layers are covered by individual electrode layers, e.g. of Aluminum. The individual photosensitive elements may partly be connected (electrically) in series and partly in parallel, depending on the requested voltage and current respectively. All photosensitive elements of the opto-electric power supply unit can be sunlit via a translucent window 8 which is left open in the non-translucent (opaque) layer 1. The electric power thus generated by means of sensor array layer 9 feeds, via conductors (not shown) on the carrier layer 4, one or more processing modules 10, which are affixed to the layer 4 and serve for (pre)processing the output of the proper light (incidence) sensor 3. The processing module may in one embodiment be arranged to process the sensor input of the sensor layer 3, typically, for determining an angle of incidence of incoming light. In another advantageous application, the processing modules can be used to calculate a total intensity amount, for example, in a predefined spectral range. Such an application for example can be used as an UV sensor having integrated opto-electric supply, wherein the processing module is provided with an output to signal a maximum predetermined dose.

Another application of interest is an opto-electric switch having integrated power supply, for example, in industrial environments wherein the interruption of a light beam causes a switching action of the opto-electric switch.

One application of the described sensor embodiment is the use as sun sensors, e.g. for (aero)space or (mobile) air conditioning applications etc. Another application may be e.g. in the field of navigation of spacecrafts, satellites etc. to detect the source direction of a laser light beam. When used in space, preferably, the carrier layer 4 is Serium doped.

FIG. 9 shows an embodiment of the invention comprising the non-translucent layer 1 deposited on the surface of the first carrier layer 4 at one side, while the sensor array layer 3 is deposited on the opposite surface of the first carrier layer 4

FIG. 10 shows an embodiment of the invention which comprises the non-translucent layer 1 deposited on the surface of the first carrier layer 4 at one side, while in this embodiment the sensor array layer 3 is not deposited on the opposite surface of the first carrier layer 4 as in the previous embodiment(s), but on the surface of a second carrier layer 11, located at the other side of the first carrier layer 4 and facing towards the first carrier layer 4. This second carrier layer 11 is e.g. made of (non-translucent, non-glassy) silicium which is more suitable for (vacuum) deposition of the sensor array layer 3 than the first carrier layer 4 due to the latter's glassy nature. For that reason the embodiment of FIG. 10 may be preferred by reason of its manufacturability. The first carrier layer 4 and the second carrier layer 11 may be assembled together by means of adhesive or anodic bonding, represented by an adhesive 12 sealing. For improving a positioning tolerance, preferably, the carrier layer 4 is polished before mounting on the second carrier layer 11.

It may be clear that both the “single substrate” embodiment of FIG. 9 and the “dual substrate” embodiment of FIG. 10 may comprise—besides the proper light sensor(s) 2,3—an integrated opto-electric power supply 8,9 as discussed in the foregoing. The same applies for the way of manufacturing: both the “single substrate” embodiment and the “dual substrate” embodiment may be made in the way indicated in FIGS. 5 and 6, viz, first making a multitude of sensors and opto-electric power cells (where appropriate) and subsequently cutting them into individual units. The sensor array may comprise photo diodes, quadrant cells, position sensitive device, CCD or active pixel sensors. In (aero)space applications, a quadrant cell embodiment is preferred, without the use of a bias voltage applied to the sensor array.

1. A light sensor, comprising:
a non-translucent layer having a first translucent aperture,
a first sensor layer comprising an opto-electrical sensor element, and
spacers between said non-translucent layer and said sensor layer, said spacers comprising a translucent solid first carrier layer located at one side of said first carrier layer and said sensor layer being located at its other side,
characterized in that said non-translucent layer comprises:
a second translucent aperture provided at said one side of said translucent first carrier layer, and
a second sensor layer comprising a plurality of opto-electrical sensor elements is provided at the other side of said translucent first carrier layer;
wherein a processing module is provided on said layer electrically connected to said first and second sensor layers, said second sensor layer providing an integrated opto-electric power supply to said processing module.

2. The light sensor according to claim 1, wherein said processing module is provided with an output to signal a maximum predetermined incident radiation dose.

3. The light sensor according to claim 1, wherein said processing module is arranged to cause a switching action of an opto-electric switch.

4. The light sensor according to claim 1, wherein said non-translucent layer is applied on a surface of said first carrier layer at said one side.

5. The light sensor according to claim 1, wherein said sensor array layer is applied on a surface of the first carrier layer at said other side.

6. The light sensor according to claim 1, wherein said sensor array layer is applied on a surface of a second carrier layer which is located at said other side of the first carrier layer.
